(19) United States
(12) Patent Application Publication
(10) Pub. No.: US 2023/0268250 A1
(43) Pub. Date: Aug. 24, 2023

(54) VAPOR CHAMBER AND MANUFACTURING METHOD OF VAPOR CHAMBER

(71) Applicant: FURUKAWA ELECTRIC CO., LTD., Tokyo (JP)

(72) Inventor: Saki TAKADA, Tokyo (JP)

(73) Assignee: FURUKAWA ELECTRIC CO., LTD., Tokyo (JP)

(21) Appl. No.: 18/002,898

(22) PCT Filed: Jun. 25, 2021
(86) PCT No.: PCT/JP2021/024250

§ 371 Date: Dec. 22, 2022

(30) Foreign Application Priority Data
Jun. 30, 2020 (JP) 2020-112761

(51) Int. Cl. H01L 23/427; H05K 7/20; F28D 15/02

(52) U.S. Cl. CPC H01L 23/427; H05K 7/20336; F28D 15/0233

(57) ABSTRACT

A vapor chamber includes a working fluid in an internal space formed between a first metal plate and a second metal plate. The first metal plate includes a plate part, and a first circumferential edge wall part which extends from a circumferential edge of the plate part toward the second metal plate. The second metal plate includes a plate part, and a second circumferential edge wall part which extends from a circumferential edge of the plate part toward the first metal plate. The vapor chamber includes a joining part and at least one extending part. The first circumferential edge wall part of the first metal plate and the second circumferential edge wall part of the second metal plate are joined by the joining part, and the extending part is joined with the joining part, and extends from the joining part.

### TECHNICAL FIELD

The present disclosure relates to a vapor chamber and a manufacturing method of a vapor chamber.

### BACKGROUND ART

For electronic components such as semiconductor elements mounted in electrical/electronic devices such as notebook computers, digital cameras and mobile telephones, size reductions have been progressing due to demands such as increased performance.

For example, Patent Document 1 discloses a heat transport device equipped with a housing configured by a cover plate and a base plate being joined, and accommodating a working fluid inside; a plurality of first tabular bodies arranged in a direction substantially orthogonal to both directions of an arrangement direction of the cover plate and the base plate, and an arrangement direction of an evaporation part and a condensation part, so as to form a first gap for communicating condensed working fluid to the evaporation part; and a gas-phase flow passage part which is formed at the circumference of each first tabular body and flows the evaporated working fluid to the condensation part.

In Patent Document 1, the circumferential edge part of the cover plate and the circumferential edge part of the bottom plate are joined. At the outer side of a side face of the heat transport device, the circumferential edge part of the cover plate, the circumferential edge part of the bottom plate, and a joining part of these (hereinafter these members are also collectively referred to as circumferential edge joining part) are provided. The circumferential edge joining part does not have a cooling function of the heat transport device. For this reason, the heat transport device of Patent Document 1 is insufficient in addressing the demand for size reduction. In addition, with a heat transport device such as a vapor chamber, the mechanical strength may decline as size reductions progress.
Patent Document 1: Japanese Unexamined Patent Application, Publication No. 2007-113864

### DISCLOSURE OF THE INVENTION

### Problems to be Solved by the Invention

An object of the present disclosure is to provide a vapor chamber having superior in mechanical strength while achieving a size reduction, as well as a manufacturing method of the vapor chamber.

### Means for Solving the Problems

According to a first aspect of the present disclosure, a vapor chamber includes a working fluid in an internal space formed between a first metal plate and a second metal plate, in which the first metal plate comprises a plate part, and a first circumferential edge wall part which extends from a circumferential edge of the plate part toward the second metal plate; the second metal plate comprises a plate part, and a second circumferential edge wall part which extends from a circumferential edge of the plate part toward the first metal plate; the vapor chamber comprises a joining part and at least one extending part; the first circumferential edge wall part of the first metal plate and the second circumferential edge wall part of the second metal plate are joined by the joining part; and the extending part is joined with the joining part, and extends from the joining part.

According to a second aspect of the present disclosure, in the vapor chamber as described in the first aspect, at least one of the extending parts extends from the joining part toward the internal space of the vapor chamber.
According to a third aspect of the present disclosure, in the vapor chamber as described in the second aspect, the extending part contacts at least one inner surface among an inner surface of the plate part of the first metal plate and an inner surface of the plate part of the second metal plate.
According to a fourth aspect of the present disclosure, in the vapor chamber as described in the second or third aspect, the extending part includes at least one groove part which is provided to a surface and extends in a direction distancing from the joining part.
According to a fifth aspect of the present disclosure, in the vapor chamber as described in any one of the first to fourth aspects, at least one of the extending parts extend from the joining part toward outside of the vapor chamber.
According to a sixth aspect of the present disclosure, a manufacturing method of the vapor chamber as described in any one of the first to fifth aspects includes a laser processing step of forming the joining part and the extending part by laser.

### Effects of the Invention

According to the present disclosure, it is possible to provide a vapor chamber having superior in mechanical strength while achieving a size reduction, as well as a manufacturing method of the vapor chamber.

### BRIEF DESCRIPTION OF THE DRAWINGS

FIG. 1 is a perspective view showing an example of a vapor chamber of an embodiment.

FIG. 2 is an enlarged cross-sectional view of a plane A in FIG. 1.

FIG. 3 is a perspective view showing another example of an extending part constituting the vapor chamber of the embodiment.

FIG. 4 is an enlarged cross-sectional view showing another example of an extending part constituting the vapor chamber of the embodiment.

FIG. 5 is an enlarged cross-sectional view showing another example of an extending part constituting the vapor chamber of the embodiment.

FIG. 6 is an enlarged cross-sectional view showing another example of an extending part constituting the vapor chamber of the embodiment.

FIG. 7 is an enlarged cross-sectional view showing another example of an extending part constituting the vapor chamber of the embodiment.

FIG. 8 is a front view looking at the extending part in FIG. 7 from an internal space of the vapor chamber.

FIG. 9 is a perspective view showing another example of an extending part constituting the vapor chamber of the embodiment.

FIG. 10 is an enlarged cross-sectional view of a plane B in FIG. 9.

FIG. 11 is an enlarged cross-sectional view showing another example of an extending part constituting the vapor chamber of the embodiment.

### PREFERRED MODE FOR CARRYING OUT THE INVENTION

Hereinafter, an embodiment will be explained in detail.

The present inventors, as a result of thorough examination, improved mechanical strength while achieving a size reduction, by focusing on the configuration of a joining part which joins a first metal plate and a second metal plate.

A vapor chamber of the embodiment includes a working fluid in an internal space formed between a first metal plate and a second metal plate, in which the first metal plate comprises a plate part, and a first circumferential edge wall part which extends from a circumferential edge of the plate part toward the second metal plate; the second metal plate comprises a plate part, and a second circumferential edge wall part which extends from a circumferential edge of the plate part toward the first metal plate; the vapor chamber comprises a joining part and at least one extending part; the first circumferential edge wall part of the first metal plate and the second circumferential edge wall part of the second metal plate are joined by the joining part; and the extending part is joined with the joining part, and extends from the joining part. Herein, the first circumferential edge wall part is corresponding to a circumferential edge wall part 12 of the first metal plate 10, and the second circumferential edge wall part is corresponding to a circumferential edge wall part 22 of the second metal plate 20. Hereinafter, the circumferential edge wall part 12 of the first metal plate 10 is also referred to as first circumferential edge wall part 12, and the circumferential edge wall part 22 of the second metal plate 20 is also referred to as second circumferential edge wall part 22.

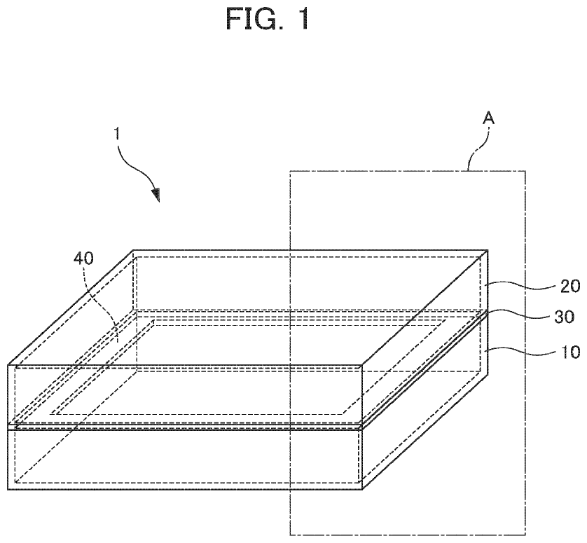

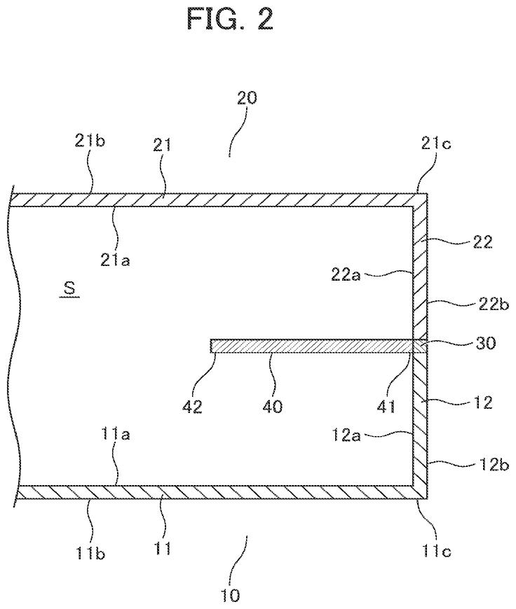

FIG. 1 is a perspective view showing an example of a vapor chamber according to the embodiment. FIG. 2 is an enlarged cross-sectional view of a plane A in FIG. 1. It should be noted that, for convenience, FIG. 1 shows an aspect partially penetrating so that the internal structure of the vapor chamber is understood.

As shown in FIGS. 1 and 2, the vapor chamber 1 of the embodiment has a first metal plate 10 and a second metal plate 20. The first metal plate 10 and the second metal plate 20 are jointed so that the first metal plate 10 and the second metal plate 20 are opposing. In other words, the first metal plate 10 and the second metal plate 20 have the insides closed. In addition, the vapor chamber 1 has a working fluid in an internal space S formed between the first metal plate 10 and the second metal plate 20. The internal space S is sealed by the first metal plate 10 and the second metal plate 20. The working fluid is enclosed in the internal space S provided inside of the vapor chamber 1.

As the working fluid enclosed in the internal space S, pure water, ethanol, methanol, acetone, fluorine based solvent, etc. can be exemplified from the viewpoint of cooling performance of the vapor chamber 1.

As shown in FIG. 2, the first metal plate 10 constituting the vapor chamber 1 has a plate part 11 and the first circumferential edge wall part 12. The first circumferential edge wall part 12 of the first metal plate 10 extends from the circumferential edge 11c of the plate part 11 toward the second metal plate 20. For example, the first circumferential edge wall part 12 is provided over the entire circumferential edge of the plate part 11.

The second metal plate 20 constituting the vapor chamber 1 has a plate part 21 and the second circumferential edge wall part 22. The plate part 21 of the second metal plate 20 opposes the plate part 11 of the first metal plate 10. In other words, the inner surface 21a of the plate part 21 of the second metal plate 20 and the inner surface 11a of the plate part 11 of the first metal plate 10 oppose each other. The second circumferential edge wall part 22 of the second metal plate 20 extends from the circumferential edge 21c of the plate part 21 toward the first metal plate 10. For example, the second circumferential edge wall part 22 is provided over the entire circumferential edge of the plate part 21.

The vapor chamber 1 includes the joining part 30 and at least one extending part 40.

At the joining part 30, the first circumferential edge wall part 12 of the first metal plate 10 and the second circumferential edge wall part 22 of the second metal plate 20 are joined. By the first circumferential edge wall part 12 extending toward the circumferential edge 21c of the second metal plate 20 and the second circumferential edge wall part 22 extending toward the circumferential edge 11c of the first metal plate 10 being joined at the joining part 30, the internal space S provided inside of the vapor chamber 1 is sealed.

At a portion including the first circumferential edge wall part 12 and the second circumferential edge wall part 22, i.e. the side wall of the vapor chamber 1, the joining part 30 is provided. In the case of the first circumferential edge wall part 12 being provided over the entire circumferential edge of the plate part 11, and the second circumferential edge wall part 22 being provided over the entire circumferential edge of the plate part 21, the joining part 30 is provided to the entire circumference of the side wall of the vapor chamber 1.

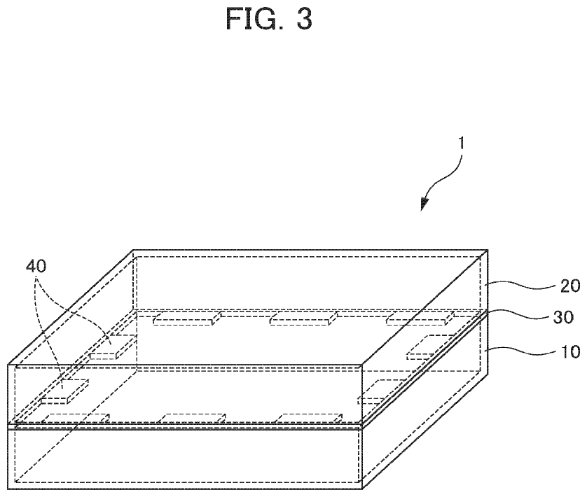

The extending part 40 is joined with the joining part 30, and extends from the joining part 30. More specifically, the base end 41 of the extending part 40 joins with the joining part 30. The extending part 40 may extend from the entirety of the joining part 30 as shown in FIG. 1, or may extend from part of the joining part 30 as shown in FIG. 3. In this way, the vapor chamber 1 may include one extending part 40 over the entirety as shown in FIG. 1, or may include a plurality of extending parts 40 as shown in FIG. 3.

Compared to the circumferential edge joining part of a conventional vapor chamber at which the circumferential edge part of the first metal plate and the circumferential edge part of the second metal plate are joined, the length of the extending part 40 from the base end 41 to the leading end 42 is very short. From the viewpoint of a size reduction of the vapor chamber 1, the length of the extending part 40 is preferably 10 mm or less.

In this way, with the vapor chamber 1, the joining part 30 joins the first circumferential edge wall part 12 extending from the circumferential edge 11c of the plate part 11 toward the second metal plate 20, and the second circumferential edge wall part 22 extending from the circumferential edge 21c of the plate part 21 toward the first metal plate 10. In other words, the joining part 30 differs from the conventional vapor chamber in which the circumferential edge part of the first metal plate and the circumferential edge part of the second metal plate are joined, and does not join the circumferential edge 11c of the first metal plate 10 and the circumferential edge 21c of the second metal plate 20. For this reason, the vapor chamber 1 of the embodiment can be reduced in size by the length corresponding to the circumferential edge joining part of the conventional vapor chamber. In addition, when increasing the internal space S of the vapor chamber 1 by the length corresponding to the circumferential edge joining part of the conventional vapor chamber, it is possible to improve the heat transport characteristic of the vapor chamber 1, without increasing the size of the vapor chamber 1 more than that of the conventional vapor chamber.

Furthermore, the extending part 40 connected to the joining part 30 is supporting the first circumferential edge wall part 12 of the first metal plate 10 and the second circumferential edge wall part 22 of the second metal plate 20 which are abutting each other, from the inner side in the thickness direction of the vapor chamber 1. Accompanying a size reduction and thickness reduction of the vapor chamber, even if the first metal plate 10 and the second metal plate 20 are reduced in thickness, since the first circumferential edge wall part 12 and the second circumferential edge wall part 22 which are reduced in thickness are reliably supported by the extending part 40, the joining strength of the first circumferential edge wall part 12 and the second circumferential edge wall part 22 is sufficiently high. In addition, as mentioned above, the extending part 40 differs from the circumferential edge joining part of the conventional vapor chamber in which the circumferential edge part of the first metal plate and the circumferential edge part of the second metal plate are joined, and is very small. For this reason, the vapor chamber 1 has superior mechanical strength, while achieving a size reduction.

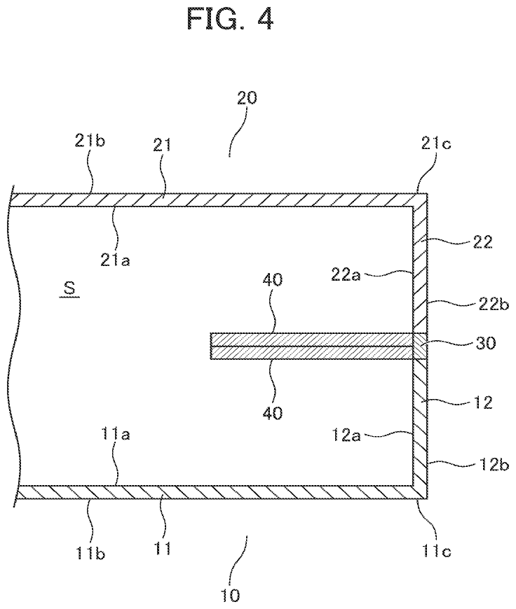

FIG. 4 is an enlarged cross-sectional view showing another example of the extending part 40 constituting the vapor chamber 1. As shown in FIG. 4, a plurality of the extending parts 40 may extend from the same position of the joining part 30. When the vapor chamber 1 includes a plurality of the extending parts 40 which extend from the joining part 30, the mechanical strength of the vapor chamber 1 further improves.

In addition, as shown in FIG. 2, at least one of the extending parts 40 preferably extends from the joining part 30 toward the internal space S of the vapor chamber 1. The extending part 40 extending toward the internal space S supports the first circumferential edge wall part 12 and the second circumferential edge wall part 22 from the inside of the vapor chamber 1.

When the extending part 40 extends from the joining part 30 toward the internal space S of the vapor chamber 1, the entirety of the extending part 40 is provided inside of the vapor chamber 1. For this reason, the vapor chamber 1 can be further reduced in size.

Furthermore, when the extending part 40 extends toward the internal space S of the vapor chamber 1, a configuration corresponding to the circumferential edge joining part of the conventional vapor chamber will not be provided at the outer side of the vapor chamber 1, i.e. outer surface of the side wall of the vapor chamber 1. For this reason, a post-process of removing a conventional such circumferential edge joining part is unnecessary. Furthermore, a burr will not be provided at the outer surface of the side wall of the vapor chamber 1. For this reason, surface shaping processing is unnecessary. In this way, it is possible to simplify manufacturing of the vapor chamber 1.

When all of the extending parts 40 extend from the joining part 30 toward the internal space S of the vapor chamber 1, the size reduction of the vapor chamber 1 and the simplicity of the manufacturing method of the vapor chamber 1 further improve.

In addition, the extending part 40 preferably contacts at least one inner surface among the inner surface 11a of the plate part 11 of the first metal plate 10 and the inner surface 21a of the plate part 21 of the second metal plate 20.

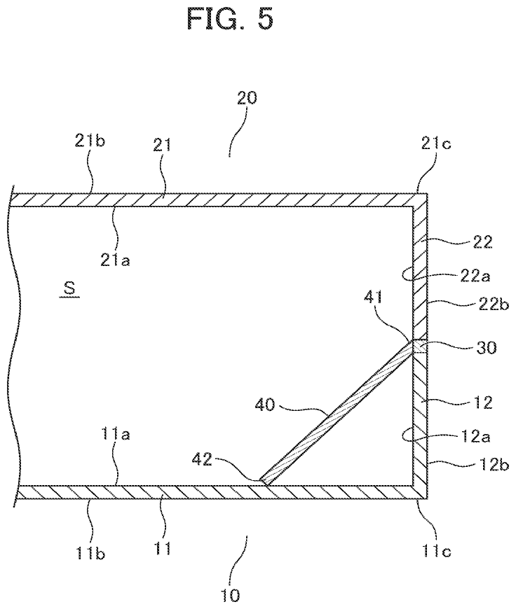

As shown in FIG. 5, for example, the leading end 42 of the extending part 40 preferably contacts the inner surface 11a of the plate part 11 of the first metal plate 10. When the extending part 40 extending toward the internal space S of the vapor chamber 1 contacts the inner surface 11a of the plate part 11 of the first metal plate 10, the extending part 40 supports the plate part 11 from the inside of the vapor chamber 1, in addition to the first circumferential edge wall part 12. For this reason, the mechanical strength of the vapor chamber 1 further improves.

In addition, when the leading end 42 of the extending part 40 contacts the inner surface 21a of the plate part 21 of the second metal plate 20, the extending part 40 supports the plate part 21 from the inside of the vapor chamber 1, in addition to the second circumferential edge wall part 22. For this reason, the mechanical strength of the vapor chamber 1 further improves.

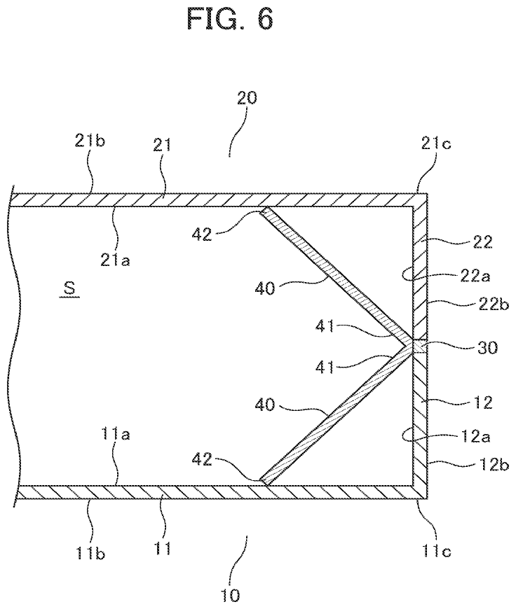

As shown in FIG. 6, if the vapor chamber 1 includes the extending part 40 contacting the inner surface 11a of the plate part 11 of the first metal plate 10 and the extending part 40 contacting the inner surface 21a of the plate part 21 of the second metal plate 20, these extending parts 40 support the first circumferential edge wall part 12 and the second circumferential edge wall part 22, as well as the plate part 11 and the plate part 21 from the inside of the vapor chamber 1. For this reason, the mechanical strength of the vapor chamber 1 further improves.

In addition, the extending part 40 preferably includes at least one groove part 43 that is provided to the surface and extends in a direction distancing from the joining part 30.

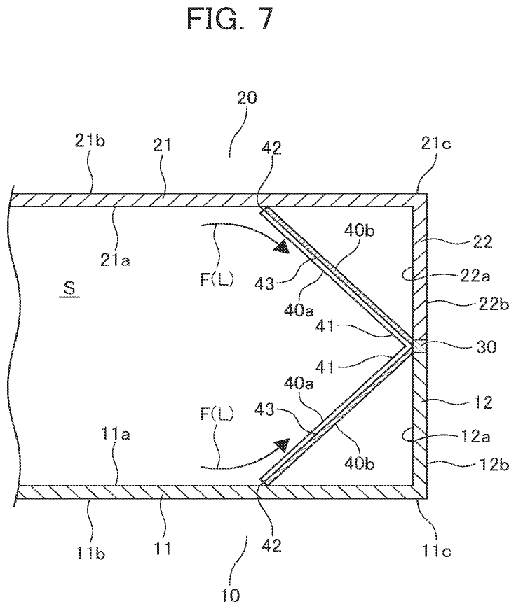

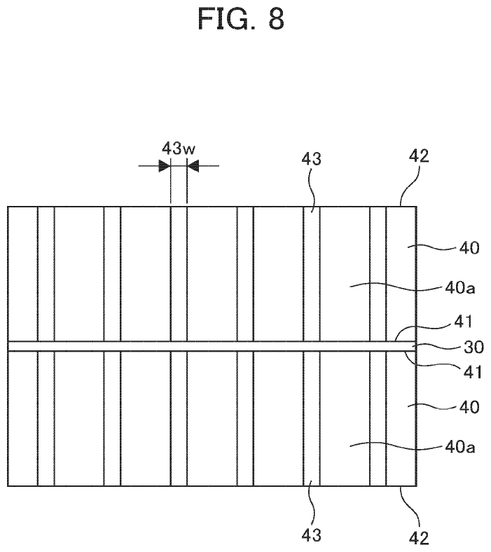

FIG. 7 is an enlarged cross-sectional view showing another example of the extending part 40 constituting the vapor chamber. FIG. 8 is a front view looking at the extending part 40 in FIG. 7 from the internal space S of the vapor chamber 1. FIG. 7 shows the direction of flow of the liquid-phase working fluid F(L) by black arrows. As shown in FIGS. 7 and 8, for example, the extending part 40 preferably includes at least one groove part 43 provided at the first surface 40a of the extending part 40, and extending from the base end 41 of the extending part 40 toward the leading end 42. Since the groove width 43w of the groove part 43 is very minute, the groove part 43 exhibits a capillary phenomenon on the liquid-phase working fluid.

When providing the groove part 43 to the extending part 40 of which the inner surface 11a of the plate part 11 contacts the leading end 42, the liquid-phase working fluid filled in the internal space of the vapor chamber 1 easily enters into the groove part 43 from the inner surface 11a of the plate part 11 as shown by the arrow F(L), by the capillary phenomenon from the groove part 43, and migrates to the base end 41 of the extending part 40 along the groove part 43. In this way, the liquid-phase working fluid is drawn up from the inner surface 11a of the plate part 11 and migrates toward a heat source which is not illustrated. In this way, since the liquid-phase working fluid favorably circulates in the internal space S, the heat transport characteristic of the vapor chamber 1 improves.

In addition, when providing the groove part 43 to the extending part 40 of which the inner surface 21a of the plate part 21 contacts the leading end 42, the liquid-phase working fluid easily enters into the groove part 43 from the inner surface 21a of the plate part 21 as shown by the arrow F(L), by the capillary phenomenon from the groove part 43, and migrates to the base end 41 of the extending part 40 along the groove part 43. In this way, the liquid-phase working fluid is suctioned from the inner surface 21a of the plate part 21 and migrates toward a heat source which is not illustrated. In this way, since the liquid-phase working fluid favorably circulates in the internal space S, the heat transport characteristic of the vapor chamber 1 improves.

When the groove part 43 extends from the base end 41 to the leading end 42 of the extending part 40, since circulation of the liquid-phase working fluid becomes more favorable, the heat transport characteristic of the vapor chamber 1 further improves. When providing the groove part 43 to both the extending part 40 of which the inner surface 11a of the plate part 11 contacts the leading end 42, and the extending part 40 of which the inner surface 21a of the plate part 21 contacts the leading end 42, since the amount of liquid-phase working fluid migrating from the inner surface of the vapor chamber 1 increases, the heat transport characteristic of the vapor chamber 1 further improves.

FIGS. 7 and 8 show an example in which the groove part 43 is provided to the first surface 40a. The first surface 40a is a face of the extending part 40 at which extending parts 40 are facing each other, i.e. The first surface 40a faces the inner side of the vapor chamber 1. The groove part 43 may be provided to the second surface 40b of the extending part 40. The second surface 40b is a back surface of the first surface, and faces the outer side of the vapor chamber 1.

Even if the groove part 43 is provided at the second surface 40b of the extending part 40, it will exhibit similar effects as the groove part 43 provided to the first surface 40a. Compared to the groove part 43 provided to the second surface 40b, since the groove part 43 provided to the first surface 40a efficiently circulates the liquid-phase working fluid, the heat transport characteristic of the vapor chamber 1 improves.

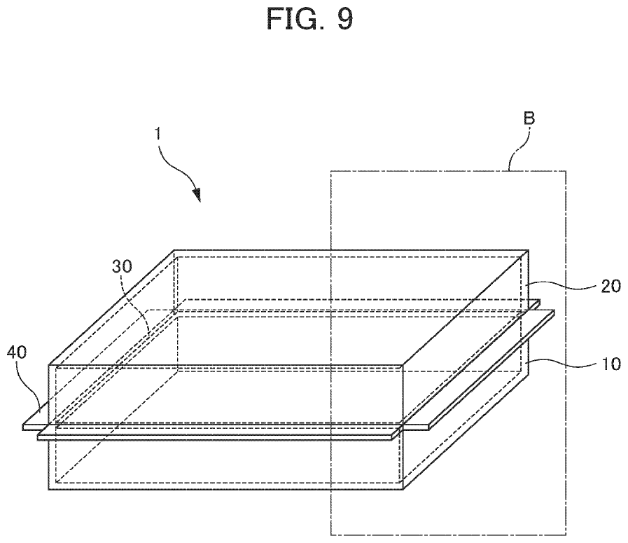

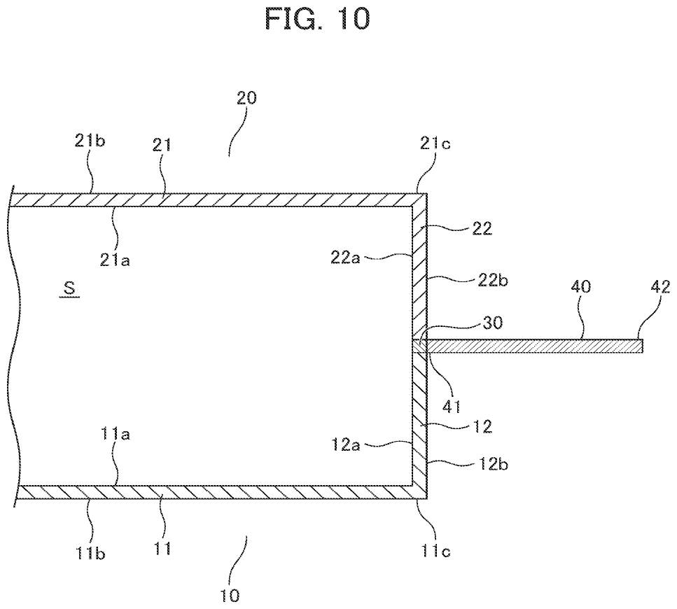

FIG. 9 is a perspective view showing another example of the extending part 40 constituting the vapor chamber 1. FIG. 10 is an enlarged cross-sectional view of the plane B in FIG. 9. As shown in FIGS. 9 and 10, at least one of the extending parts 40 may extend from the joining part 30 toward the outside of the vapor chamber 1.

As described above, the extending part 40 is very small, contrary to the circumferential edge joining part of the conventional vapor chamber at which the circumferential edge part of the first metal plate and the circumferential edge part of the second metal plate are joined. Even if the extending part 40 joined to the joining part 30 extends to the outside of the vapor chamber 1, compared to the conventional vapor chamber, the vapor chamber 1 of the embodiment can be reduced in size.

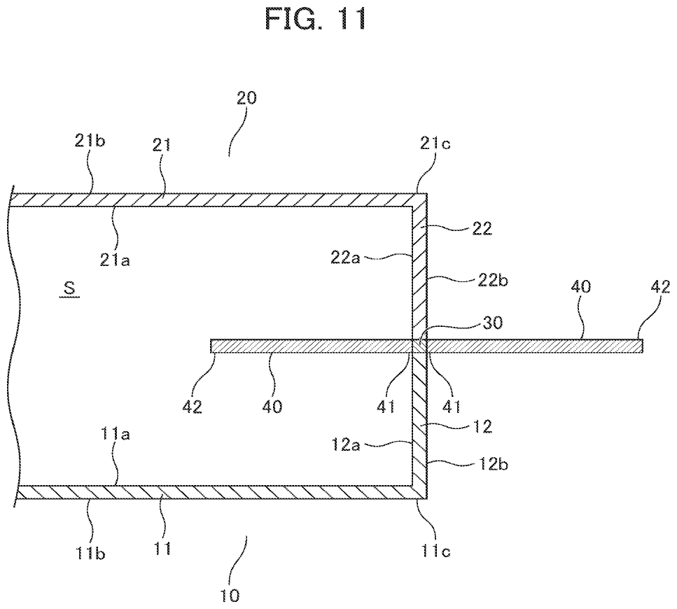

For example, the vapor chamber 1 may include the extending part 40 extending from the joining part 30 toward the internal space S of the vapor chamber 1 and the extending part 40 extending from the joining part 30 toward the outside of the vapor chamber 1, as shown in FIG. 11.

In the formation of the joining part 30 and the extending part 40 which are reducing the size of the vapor chamber 1 and improving mechanical strength, processing using a laser is preferable, and thereamong, processing using a fiber laser is more preferable. In the processing by laser, it is possible to locally join the first circumferential edge wall part 12 of the first metal plate 10 and the second circumferential edge wall part 22 of the second metal plate 20 in a short time. As a result thereof, it is possible to achieve a size reduction and improvement in mechanical strength of the vapor chamber 1.

In addition, the material constituting the first metal plate 10 and the second metal plate 20 is preferably copper, copper alloy, aluminum, aluminum alloy or stainless steel, from the viewpoint of high thermal conductivity, processing ease by laser, etc. Thereamong, for the purpose of achieving weight reduction, aluminum or aluminum alloy is more preferable, and for the purpose of raising the mechanical strength, stainless steel is more preferable. In addition, depending on the use environment, tin, tin alloy, titanium, titanium alloy, nickel, nickel alloy, etc. may be used in the first metal plate 10 and the second metal plate 20.

A heat generating body which is not illustrated is mounted to the outer surface 10b of the first metal plate 10 and/or the outer surface 20b of the second metal plate 20. When the vapor chamber 1 and the heat generating body are thermally connected, the heat generating body is cooled by the vapor chamber. The heat generating body is a member such as an electronic component which generates heat during operation, such as a semiconductor element, for example.

Next, a manufacturing method of the above-mentioned vapor chamber 1 will be explained.

The manufacturing method of the vapor chamber 1 has a laser processing step of forming the joining part 30 and the extending part 40 by laser. In the laser processing step, it is preferable to form the joining part 30 and the extending part 40 by a fiber laser. The laser processing is superior in processing control to locally join the first circumferential edge wall part 12 of the first metal plate 10 and the second circumferential edge wall part 22 of the second metal plate 20, and can form the joining part 30 in a short time. In addition, since the first circumferential edge wall part 12 and the second circumferential edge wall part 22 become the target of the laser irradiation, even if the first metal plate 10 and the second metal plate 20 are made thinner accompanying a size reduction and a thickness reduction of the vapor chamber, the joining between the thickness reduced first circumferential edge wall part 12 and the thickness reduced second circumferential edge wall part 22 is easy. Furthermore, while forming the joining part 30, the extending part 40 is simultaneously formed. Among lasers, the fiber laser is more superior in processing control and short-time processing.

More specifically, in a state in which the inner surface 11a of the plate part 11 and the inner surface 21a of the plate part 21 are facing each other, and the first circumferential edge wall part 12 and the second circumferential edge wall part 22 are contacting each other, the laser is irradiated onto the contacting portion of the first circumferential edge wall part 12 and the second circumferential edge wall part 22. For example, in a state in which the first circumferential edge wall part 12 and the second circumferential edge wall part 22 are contacting each other, the laser is irradiated from outside. When irradiating the laser while scanning onto the entirety of the contacting portion of the first circumferential edge wall part 12 and the second circumferential edge wall part 22, it is possible to manufacture the vapor chamber 1 by one-time laser irradiating. The extending direction of the extending part 40, the presence or absence of the extending part 40, etc. can be easily controlled by the contact force between the first circumferential edge wall part 12 and the second circumferential edge wall part 22, the irradiation conditions of the laser, etc.

The vapor chamber 1 manufactured by the above is suitably used in electronic devices such as portable telephones, for which good heat transport characteristics are required even in various postures. The electronic device equipped with the vapor chamber 1 has high heat transport characteristics of the vapor chamber 1, even in various usage states.

According to the above explained embodiment, the first circumferential edge wall part of the first metal plate and the second circumferential edge wall part of the second metal plate are joined via the joining part. For this reason, the vapor chamber can be reduced in size. In addition, the first circumferential edge wall part of the first metal plate and the second circumferential edge wall part of the second metal plate are supported from the inner side in the thickness direction of the vapor chamber by the extending part connected to the joining part. For this reason, the vapor chamber has superior mechanical strength, while achieving a size reduction.

It should be noted that the extending part 40 extending toward the outside of the vapor chamber 1 shown in FIGS. 9 to 11 is very small as described above. For this reason, with respect to the vapor chamber 1, it may not necessarily remove such an extending part 40. However, depending on the desired requirements, the extending part 40 which is extending toward the outside of the vapor chamber 1 may be removed from the vapor chamber 1.

Although an embodiment has been explained above, the present invention encompasses all aspects included in the gist of the present disclosure and the claims without being limited to the above-mentioned embodiment, and can be modified in various ways within the scope of the present disclosure.

### EXPLANATION OF REFERENCE NUMERALS

1 vapor chamber
10 first metal plate
11 plate part
11a inner surface of plate part
11b outer surface of plate part
11c circumferential edge of plate part
12 circumferential edge wall part of first metal plate (first circumferential edge wall part)
12a inner surface of first circumferential edge wall part
12b outer surface of first circumferential edge wall part
20 second metal plate
21 plate part
21a inner surface of plate part
21b outer surface of plate part
21c circumferential edge of plate part
22 circumferential edge wall part of second metal plate (second circumferential edge wall part)
22a inner surface of second circumferential edge wall part
22b outer surface of second circumferential edge wall part
30 joining part
40 extending part
40a surface of extending part (first surface)
40b surface of extending part (second surface)
41 base end of extending part
42 leading end of extending part
43 groove part
S internal space
F(L) flow of liquid-phase working fluid

1. A vapor chamber having a working fluid in an internal space formed between a first metal plate and a second metal plate,
wherein the first metal plate comprises a plate part, and a first circumferential edge wall part which extends from a circumferential edge of the plate part toward the second metal plate,
wherein the second metal plate comprises a plate part, and a second circumferential edge wall part which extends from a circumferential edge of the plate part toward the first metal plate,
wherein the vapor chamber comprises a joining part and at least one extending part,
wherein the first circumferential edge wall part of the first metal plate and the second circumferential edge wall part of the second metal plate are joined by the joining part, and
wherein the extending part is joined with the joining part, and extends from the joining part.

2. The vapor chamber according to claim 1, wherein at least one of the extending parts extends from the joining part toward the internal space of the vapor chamber.

3. The vapor chamber according to claim 2, wherein the extending part contacts at least one inner surface among an inner surface of the plate part of the first metal plate and an inner surface of the plate part of the second metal plate.

4. The vapor chamber according to claim 2, wherein the extending part includes at least one groove part which is provided to a surface and extends in a direction distancing from the joining part.

5. The vapor chamber according to claim 1, wherein at least one of the extending parts extend from the joining part toward outside of the vapor chamber.

6. A manufacturing method of the vapor chamber according to claim 1, the manufacturing method comprising:
a laser processing step of forming the joining part and the extending part by laser.

7. The vapor chamber according to claim 3, wherein the extending part includes at least one groove part which is provided to a surface and extends in a direction distancing from the joining part.

8. The vapor chamber according to claim 2, wherein at least one of the extending parts extend from the joining part toward outside of the vapor chamber.

9. A manufacturing method of the vapor chamber according to claim 2, the manufacturing method comprising:
a laser processing step of forming the joining part and the extending part by laser.

10. The vapor chamber according to claim 3, wherein at least one of the extending parts extend from the joining part toward outside of the vapor chamber.

11. A manufacturing method of the vapor chamber according to claim 3, the manufacturing method comprising:
a laser processing step of forming the joining part and the extending part by laser.

12. The vapor chamber according to claim 4, wherein at least one of the extending parts extend from the joining part toward outside of the vapor chamber.

13. A manufacturing method of the vapor chamber according to claim 4, the manufacturing method comprising:
a laser processing step of forming the joining part and the extending part by laser.

14. A manufacturing method of the vapor chamber according to claim 5, the manufacturing method comprising:
a laser processing step of forming the joining part and the extending part by laser.
